(19) United States
(12) Patent Application Publication
(10) Pub. No.: US 2016/0035601 A1
(43) Pub. Date: Feb. 4, 2016

(54) BAKE UNIT, SUBSTRATE TREATING APPARATUS INCLUDING THE UNIT, AND SUBSTRATE TREATING METHOD

(71) Applicant: SEMES CO., LTD., Chungcheongnam-do (KR)

(72) Inventors: Ki Sang Eum, Chungcheongnam-do (KR); Jong Seok Seo, Chungcheongnam-do (KR)

(21) Appl. No.: 14/805,743

(22) Filed: Jul. 22, 2015

(30) Foreign Application Priority Data
Jul. 31, 2014 (KR) 10-2014-0098533

(51) Int. Cl. H01L 21/67; H01L 21/677

(52) U.S. Cl. CPC H01L 21/67103; H01L 21/67733; H01L 21/67098

(57) ABSTRACT

The inventive concepts relate to a bake unit and a substrate treating apparatus including the same. The bake unit includes a housing, a heating unit located in the housing and including a heating plate heating a substrate, a transfer unit located in the housing and transferring a substrate, and a cooling unit cooling the heating plate or a heated substrate. The transfer unit includes a transfer plate on which a substrate is laid, and the cooling unit is provided to the transfer plate.

### CROSS-REFERENCE TO RELATED APPLICATION

This U.S. non-provisional patent application claims priority under 35 U.S.C. §119 to Korean Patent Application No. 10-2014-0098533, filed on Jul. 31, 2014, in the Korean Intellectual Property Office, the disclosure of which is hereby incorporated by reference in its entirety.

### BACKGROUND

The inventive concepts relate to an apparatus and a method for treating a substrate. More particularly, the inventive concepts relate to a bake unit heating a substrate, a substrate treating apparatus including the unit, and a substrate treating method.

Generally, various processes such as cleaning, deposition, photolithography, etching, and ion implantation processes are performed to fabricate a semiconductor device. The photolithography process performed for forming patterns may be important to realize a high integration density of the semiconductor device.

The photolithography process may be performed to form a photoresist pattern on a semiconductor substrate. The photolithography process may include a coating process forming a photoresist layer on a substrate, a an exposure process forming the photoresist pattern from the photoresist layer, and a development process removing a region to which light is irradiated in the exposure process or a region to which the light is not irradiated. A bake process heating and cooling the substrate may be performed after and before each of the coating, exposure, and development processes.

The bake process may heat the substrate by a heating unit. The heating unit may have a heating plate on which a wafer is loaded. After a process performed on wafers included in one group is completed, a temperature of the heating plate should be adjusted to be suitable for a process condition (e.g., heating temperature) of wafers included in the next group before a process of the wafers included in the next group is performed. The temperature rise of the heating plate may be rapidly performed by increasing heat energy provided to the heating plate. However, the temperature of the heating plate may drop by a natural cooling method, and thus, a time required to drop the temperature may increase. The time required by natural cooling method may correspond to a waiting time of equipment, so a operation rate of the equipment may be markedly reduced.

### SUMMARY

Embodiments of the inventive concepts may provide a bake unit capable of improving efficiency of a bake process, a substrate treating apparatus including the same, and a substrate treating method.

Embodiments of the inventive concepts may also provide a bake unit capable of improving a cooling rate of a bake plate, a substrate treating apparatus including the same, and a substrate treating method.

In one aspect, a bake unit may include a housing, a heating unit located in the housing and including a heating plate heating a substrate, a transfer unit located in the housing and transferring a substrate, and a cooling unit cooling the heating plate or a heated substrate. The transfer unit may include a transfer plate on which a substrate is laid, and the cooling unit may be provided to the transfer plate.

In an embodiment, the cooling unit may include a cooling fluid path provided within the transfer plate.

In an embodiment, the housing may include a first sidewall through which an entrance is formed, and a second sidewall opposite to the first sidewall. A substrate may be transferred through the entrance. The heating unit may be located to be more adjacent to the second sidewall than to the first sidewall.

In an embodiment, the heating unit may further include a cover disposed on the heating plate and providing a heating space including the heating plate; and an actuator moving the cover in up and down directions.

In an embodiment, the heating unit may further a lift pin movable through a pin hole, formed in the heating plate, along up and down directions. The lift pin may transfer a substrate to the transfer unit.

In an embodiment, the transfer unit may further include a driving member transferring the transfer plate to a first position and a second position. The first position may be adjacent to the first sidewall, and the second position may be near to the second sidewall and may be over the heating plate.

In an embodiment, a guide hole into which the lift pin is inserted may be formed in the transfer plate to prevent the transfer plate from interfering or colliding with the lift pin when the transfer plate is moved from the first position to the second position. The guide hole may extend from an outer side surface of the transfer plate to the inside of the transfer plate.

In an embodiment, the bake unit may further include a controller controlling the transfer unit and the cooling unit. When a temperature of the heating plate is reduced, the controller may control the transfer unit and the cooling unit in such a way that the transfer plate comes in contact with or is located to be adjacent to the heating plate and then the heating plate is cooled by the cooling unit.

In an embodiment, the bake unit may further include a controller controlling the transfer unit and the cooling unit. When a substrate heated on the heating plate is cooled, the controller may control the transfer unit and the cooling unit in such a way that a substrate completely treated on the heating plate is located on the transfer plate and then the substrate is cooled using the cooling unit.

In another aspect, a substrate treating apparatus may include a bake unit performing a bake process on a substrate, a solution-treatment chamber supplying a solution onto a substrate to perform a process, and a transfer chamber transferring a substrate between the bake unit and the solution-treatment chamber. The bake unit may include a housing, a heating unit located in the housing and including a heating plate heating a substrate, a transfer unit located in the housing and transferring a substrate, and a cooling unit cooling the heating plate or a heated substrate. The transfer unit may include a transfer plate on which a substrate is laid, and the cooling unit may be provided to the transfer plate.

In an embodiment, the cooling unit may include a cooling fluid path provided within the transfer plate.

In an embodiment, the housing may include a first sidewall through which an entrance is formed, and a second sidewall opposite to the first sidewall. A substrate may be transferred through the entrance. The heating unit may be disposed to be more adjacent to the second sidewall than to the first sidewall.

In an embodiment, the heating unit may further include a cover disposed on the heating plate and providing a heating space including the heating plate, and an actuator moving the cover in up and down directions.

In an embodiment, the heating unit may further include a lift pin movable through a pin hole, formed in the heating plate, along up and down directions. The lift pin may transfer a substrate to the transfer unit.

In an embodiment, the transfer unit may further include a driving member transferring the transfer plate to a first position and a second position. The first position may be adjacent to the first sidewall, and the second position may be near to the second sidewall and may be over the heating plate.

In an embodiment, a guide hole into which the lift pin is inserted may be formed in the transfer plate to prevent the transfer plate from interfering or colliding with the lift pin when the transfer plate is moved from the first position to the second position. The guide hole may extend from an outer side surface of the transfer plate to the inside of the transfer plate.

In an embodiment, the substrate treating apparatus may further include a controller controlling the transfer unit and the cooling unit. When a temperature of the heating plate is reduced, the controller may control the transfer unit and the cooling unit in such a way that the transfer plate comes in contact with or is located to be adjacent to the heating plate and then the heating plate is cooled by the cooling unit.

In an embodiment, the substrate treating apparatus may further include a controller controlling the transfer unit and the cooling unit. When a substrate heated on the heating plate is cooled, the controller may control the transfer unit and the cooling unit in such a way that a substrate completely treated on the heating plate is located on the transfer plate and then the substrate is cooled using the cooling unit.

In still another aspect, a method for treating a substrate may include heating a first substrate included in a first group to a first temperature by a heating plate, cooling the heating plate using a cooling unit provided to a transfer plate transferring a substrate to the heating plate, and heating a second substrate included in a second group to a second temperature lower than the first temperature by the heating plate.

In an embodiment, cooling the heating plate may include cooling the heating plate using the cooling unit after the transfer plate comes in contact with or is located to be adjacent to the heating plate when a temperature of the heating plate is reduced to the second temperature.

In an embodiment, cooling the heating plate may include cooling the heating plate using the cooling unit after the transfer plate comes in contact with or is located to be adjacent to the heating plate in a state that a substrate is removed from the transfer plate.

In an embodiment, cooling the heating plate may include cooling the heating plate using a cooling gas supplied to a bottom surface of the heating plate while cooling the heating plate by the cooling unit.

In an embodiment, the method may further include cooling the first substrate using the cooling unit after locating the first substrate, completely treated after heating the first substrate to the first temperature on the heating plate, on the transfer plate. Cooling the first substrate may be performed before cooling the heating plate.

In an embodiment, the method may further include cooling the second substrate using the cooling unit after locating the second substrate, completely treated after heating the second substrate to the second temperature on the heating plate, on the transfer plate.

In an embodiment, the cooling unit may include a cooling fluid path provided within the transfer plate.

### BRIEF DESCRIPTION OF THE DRAWINGS

The inventive concepts will become more apparent in view of the attached drawings and accompanying detailed description.

FIG. 1 is a view illustrating a substrate treating apparatus according to example embodiments of the inventive concepts.

FIG. 2 is a view illustrating the substrate treating apparatus of FIG. 1 when viewed in a direction A-A.

FIG. 3 is a view illustrating the substrate treating apparatus of FIG. 1 when viewed in a direction B-B.

FIG. 4 is a perspective view illustrating a bake unit according to example embodiments of the inventive concepts.

FIG. 5 is a plan view of the bake unit of FIG. 4.

FIG. 6 is a cross-sectional view of the bake unit of FIG. 4.

FIG. 7 is a flow chart illustrating a method for treating a substrate in a bake unit according to example embodiments of the inventive concepts.

FIGS. 8 to 16 are cross-sectional views illustrating a method for treating a substrate according to example embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

An apparatus according to the present embodiments may be used to perform a photolithography process on a substrate such as a semiconductor wafer or a flat display panel. In particular, the apparatus of the present embodiments may be used to perform a coating process and a development process on the substrate.

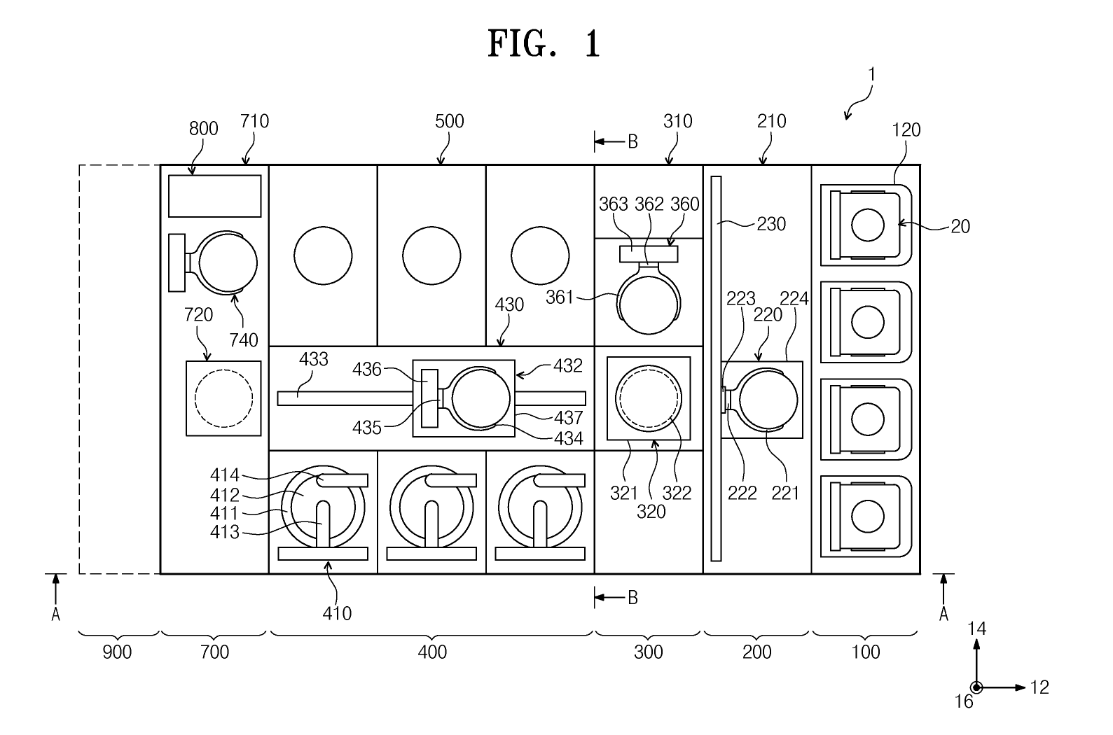

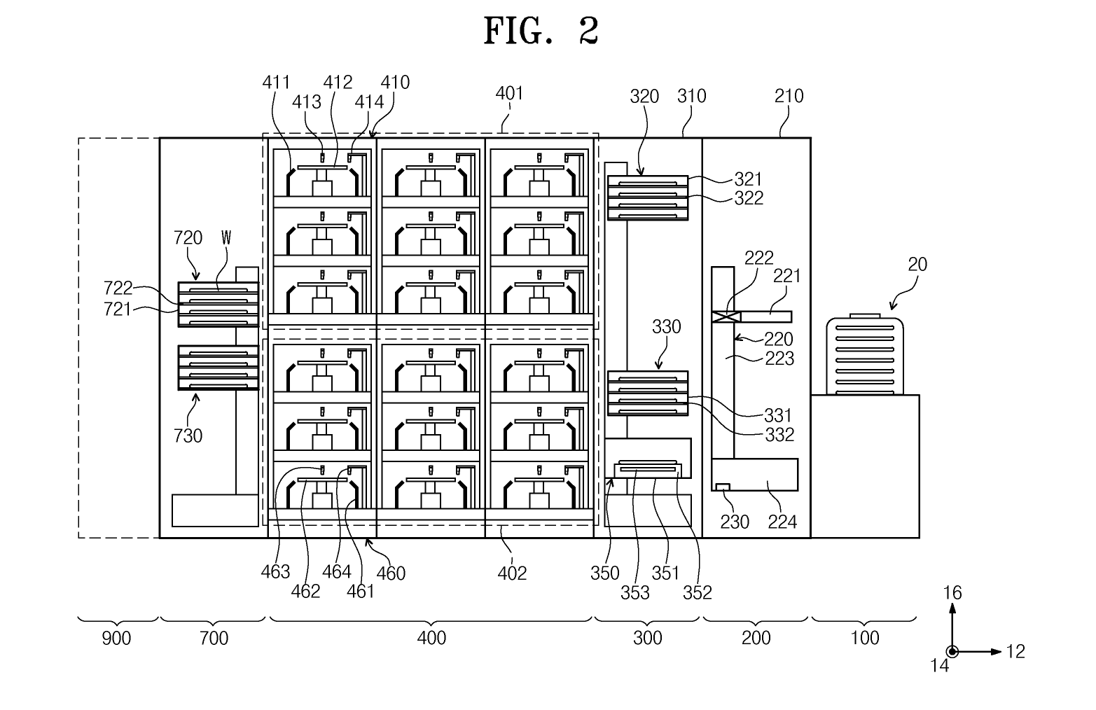

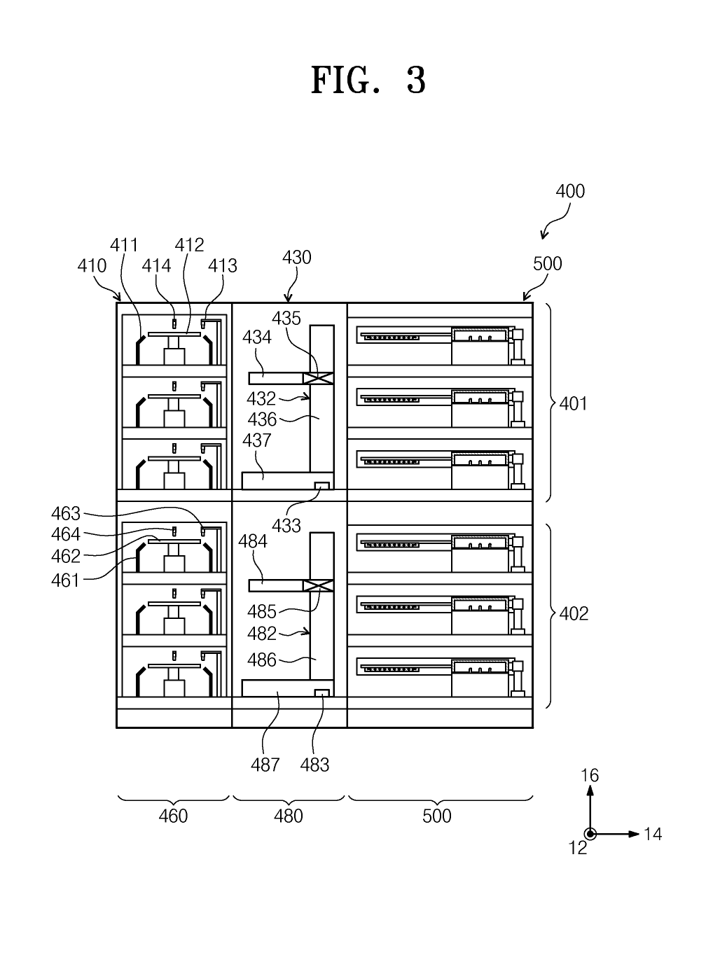

FIGS. 1 to 3 are schematic views illustrating a substrate treating apparatus 1 according to example embodiments of the inventive concepts. FIG. 1 is a view illustrating the substrate treatment apparatus 1 when viewed from a plan view, FIG. 2 is a view illustrating the substrate treating apparatus 1 of FIG. 1 when viewed in a direction A-A, and FIG. 3 is a view illustrating the substrate treating apparatus 1 of FIG. 1 when viewed in a direction B-B.

Referring to FIGS. 1, 2, and 3, the substrate treating apparatus 1 may include a load port 100, an index module 200, a buffer module 300, a coating and development module 400, an interface module 700, and a purge module 800. The load port 100, the index module 200, the buffer module 300, the coating and development module 400, and the interface module 700 may be sequentially arranged in a line along one direction. The purge module 800 may be provided in the interface module 700. Alternatively, the purge module 800 may be disposed at one of other various positions such as a rear end of the interface module 700 to which an exposure apparatus is connected, or a position at a side of the interface module 700.

Hereinafter, the direction along which the load port 100, the index module 200, the buffer module 300, the coating and development module 400, and the interface module 700 are arranged is defined as a first direction 12. A direction perpendicular to the first direction 12 when viewed from a plan view is defined as a second direction 14, and a direction perpendicular to the first and second directions 12 and 14 is defined as a third direction 16.

A substrate W may be received in a cassette 20 and may move along with the cassette 20. The cassette 20 may have a structure sealed from the outside. For example, the cassette 20 may be a front open unified pod (FOUP) having a door at its front side.

Hereinafter, the load port 100, the index module 200, the buffer module 300, the coating and development module 400, the interface module 700, and the purge module 800 will be described.

The load port 100 may have a placing table 120 on which the cassette 20 receiving substrates W is laid. The placing table 120 may be provided in plurality, and the placing tables 120 may be arranged in a line along the second direction 14.

Four placing tables 120 are provided in FIG. 1.

The index module 200 may transfer a substrate W between the buffer module 300 and the cassette 20 laid on the placing table 120 of the load port 100. The index module 200 may include a frame 210, an index robot 220, and a guide rail 230. The frame 210 may have a rectangular parallelepiped shape of which the inside is empty. The frame 210 may be disposed between the load port 100 and the buffer module 300. A height of the frame 210 of the index module 200 may be smaller than that of a frame 310, to be described later, of the buffer module 300. The index robot 220 and the guide rail 230 may be disposed in the frame 210. The index robot 220 may have a four-axis drivable structure in such a way that a hand 221 directly handling the substrate W is movable in the first, second, and third directions 12, 14, and 16 and is rotatable. The index robot 220 may include the hand 221, an arm 222, a supporter 223, and a pedestal 224. The hand 221 may be fixedly installed on the arm 222. The arm 222 may have a retractile and protrusile structure and a rotatable structure. The supporter 223 may be disposed such that its longitudinal direction is parallel to the third direction 16. The arm 222 may be coupled to the supporter 223 so as to be movable along the supporter 223. The supporter 223 may be fixedly combined with the pedestal 224. The guide rail 230 may be disposed such that its longitudinal direction is parallel to the second direction 14. The pedestal 223 may be coupled to the guide rail 230 so as to be linearly movable along the guide rail 230. In addition, even though not shown in the drawings, a door opener opening and closing the door of the cassette 20 may be further provided in the frame 210.

The buffer module 300 may include a frame 310, a first buffer 320, a second buffer 330, a cooling chamber 350, and a first buffer robot 360. The frame 310 may have a rectangular parallelepiped shape of which the inside is empty. The frame 310 may be disposed between the index module 200 and the coating and development module 400. The first buffer 320, the second buffer 330, the cooling chamber 350, and the first buffer robot 360 may be disposed in the frame 310. The cooling chamber 350, the second buffer 330, and the first buffer 320 may be sequentially arranged from a bottom of the frame 310 along the third direction 16. The first buffer 320 may be disposed at a height corresponding to a coating module 401, to be described later, of the coating and development module 400, and the second buffer 330 and the cooling chamber 350 may be disposed at a height corresponding to a development module 402, to be described later, of the coating and development module 400. The first buffer robot 360 may be spaced apart from the second buffer 330, the cooling chamber 350, and the first buffer 320 by a constant distance in the second direction 14.

Each of the first and second buffers 320 and 330 may temporarily receive a plurality of substrates W. The second buffer 330 may include a housing 331 and a plurality of supporters 332. The supporters 332 may be disposed in the housing 331 so as to be spaced apart from each other along the third direction 16. One substrate W may be put on each of the supporters 332. The housing 331 may have openings (not shown) that can face the index robot 220 and the first buffer robot 360, respectively, and thus, the index robot 220 and the first buffer robot 360 may carry a substrate W onto the supporter 332 of the housing 331 or may take a substrate W out of the supporter 332 of the housing 331. The first buffer 320 may have a similar structure to the second buffer 330. However, a housing 321 of the first buffer 320 may have openings that can face the first buffer robot 360 and a coating part robot 432 disposed in the coating module 401, respectively. The number of supporters 322 provided in the first buffer 320 may be equal to or different from the number of the supporters 332 provided in the second buffer 330. In some embodiments, the number of the supporters 332 provided in the second buffer 330 may be more than the number of the supporters 322 provided in the first buffer 320.

The first buffer robot 360 may transfer a substrate W between the first buffer 320 and the second buffer 330. The first buffer robot 360 may include a hand 361, an arm 362, and a supporter 363. The hand 361 may be fixedly installed on the arm 362. The arm 362 may have a retractile and protrusile structure, and thus, the hand 361 may be movable along the second direction 14. The arm 362 may be coupled to the supporter 363 so as to be linearly movable along the third direction 16. The supporter 363 may have a length extending from a position corresponding to the second buffer 330 to a position corresponding to the first buffer 320. In addition, the supporter 363 may further extend in an up or down direction. The first buffer robot 360 may have a two-axis drivable structure in such a way that the hand 361 is movable along the second direction 14 and the third direction 16.

The cooling chamber 350 may cool each substrate W. The cooling chamber 350 may include a housing 351 and a cooling plate 352. The cooling plate 352 may have a top surface on which a substrate W is laid. The cooling plate 352 may include a cooling member 353 cooling the substrate W. The cooling member 353 may be operated by at least one of various cooling methods such as a cooling method using cooling water, and a cooling method using a thermoelectric device. In addition, the cooling chamber 350 may further include a lift-pin assembly locating a substrate W onto the cooling plate 352. The housing 351 may have openings that can face the index robot 220 and a development part robot provided in the development module 402, respectively, and thus, the index robot 220 and the development part robot may carry a substrate W onto the cooling plate 352 or may take a substrate W out of the cooling plate 352. In addition, the cooling chamber 350 may further include doors closing and opening the above mentioned openings of the housing 351.

The coating module 401 may perform a process of coating a photosensitive solution (e.g., photoresist) on a substrate W, and a thermal treatment process of heating and cooling the substrate W before and after the coating process (e.g., a resist coating process). The coating module 401 may include a solution-treatment chamber 410, a bake unit 500, and a transfer chamber 430. The solution-treatment chamber 410, the transfer chamber 430, and the bake unit 500 may be sequentially arranged along the second direction 14. The solution-treatment chamber 410 may be provided as a resist coating chamber 410 performing the resist coating process on a substrate W. The resist coating chamber 410 may be provided in plurality. In more detail, the resist coating chamber 410 may be provided in plurality along each of the first and third directions 12 and 16. The bake unit 500 may also be provided in plurality along each of the first and third directions 12 and 16.

The transfer chamber 430 and the first buffer 320 of the buffer module 300 may be arranged along the first direction 12. The coating part robot 432 and a guide rail 433 may be disposed in the transfer chamber 430. The transfer chamber 430 may have a substantially rectangular shape when viewed from a plan view. The coating part robot 432 may transfer a substrate W among the bake units 500, the resist coating chambers 410, and the first buffer 320 of the buffer module 300. The guide rail 433 may be disposed in such a way that its longitudinal direction is parallel to the first direction 12. The guide rail 433 may guide the coating part robot 432 such that the coating part robot 432 is linearly movable in the first direction 12. The coating part robot 432 may include a hand 434, an arm 435, a supporter 436, and a pedestal 437. The hand 434 may be fixedly installed on the arm 435. The arm 435 may have a retractile and protrusile structure, and thus, the hand 434 may be movable in a horizontal direction. The supporter 436 may be disposed such that its longitudinal direction is parallel to the third direction 16. The arm 435 may be coupled to the supporter 436 so as to be linearly movable along the supporter 436 in the third direction 16. The supporter 436 may be fixedly combined with the pedestal 437, and the pedestal 437 may be coupled to the guide rail 433 so as to be movable along the guide rail 433.

The resist coating chambers 410 may have the same structure. However, kinds of photoresists respectively used in the resist coating chambers 410 may be different from each other or may be the same as each other. For example, a chemical amplification resist may be used as the photoresist. The resist coating chamber 410 may coat the photoresist on a substrate W. The resist coating chamber 410 may include a housing 411, a support plate 412, and a nozzle 413. The housing 411 may have a cup shape of which a top end is opened. The support plate 412 may be located in the housing 411 and may support a substrate W. The support plate 412 may be provided to be rotatable. The nozzle 413 may supply the photoresist onto the substrate W disposed on the support plate 412. The nozzle 413 may have a circular pipe shape and may supply the photoresist to a center of the substrate W. In other embodiments, the nozzle 413 may have a length corresponding to a diameter of the substrate W, and a discharge opening of the nozzle 413 may have a slit shape. In addition, the resist coating chamber 410 may further include a nozzle 414 that supplies a cleaning solution (e.g., deionized water) to clean a surface of the substrate W coated with the photoresist.

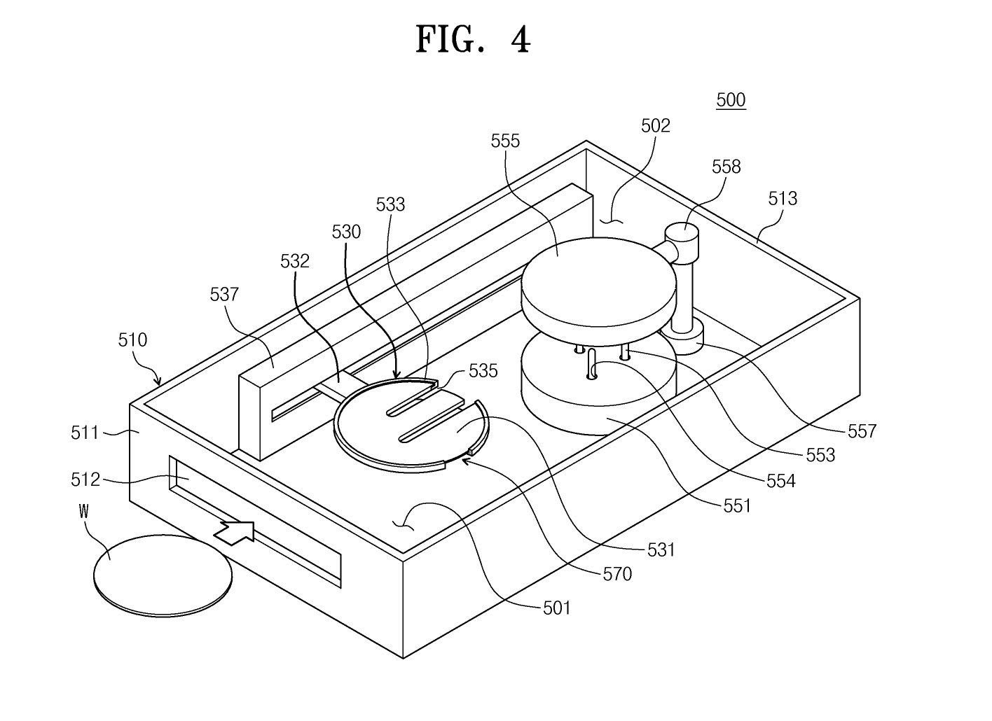

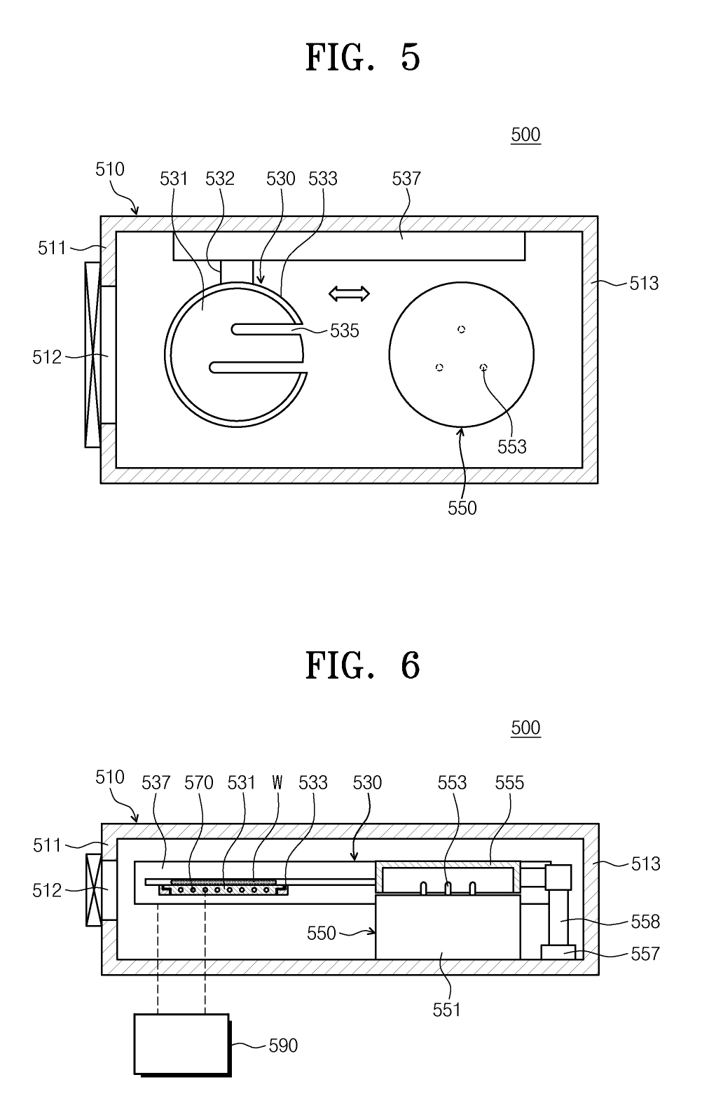

FIGS. 4 to 6 illustrate the bake unit. Referring to FIGS. 4 to 6, the bake unit 500 may thermally treat the substrate W. For example, the bake unit 500 may perform a heating process such as a pre-bake process or a soft-bake process. The pre-bake process may heat the substrate W to a predetermined temperature before coating the photoresist to remove an organic material or moisture of the surface of the substrate W. The soft-bake process may be performed after the photoresist is coated on the substrate W. In addition, the bake unit 500 may also perform a cooling process cooling the substrate W after the heating process.

The bake unit 500 may include a housing 510, a transfer unit 530, a heating unit 550, a cooling unit 570, and a controller 590.

The housing 510 may provide an inner space in which a bake process is performed. The housing 510 may have a rectangular parallelepiped shape. The housing 510 may include a first sidewall 511, a second sidewall 513, and an entrance 512.

The first sidewall 511 may correspond to one sidewall of the housing 510. The second sidewall 512 may be provided to be opposite to the first sidewall 511. The entrance 512 through the substrate W goes in and out may be formed through a sidewall of the housing 510. For example, the entrance 512 may be formed through the first sidewall 511. The entrance 512 may correspond to a path through which the substrate W moves.

The transfer unit 530 may transfer the substrate W in the housing 510. The transfer unit 530 may include a transfer plate 531, an arm 532, a support ring 533, and a driving member 537.

The substrate W may be put on the transfer plate 531. The transfer plate 531 may have a circular shape. The transfer plate 531 may have the same size as the substrate W. The transfer plate 531 may be formed of a metal material having excellent heat conductivity. A guide hole 535 may be formed in the transfer plate 531. The guide hole 535 may extend from an outer side surface of the transfer plate 531 into the inside of the transfer plate 531. The guide hole 535 may prevent the transfer plate 531 from interfering or colliding with a lift pin 553 when the transfer plate 531 moves.

The arm 532 may be fixedly combined with the transfer plate 531.

The arm 532 may be provided between the transfer plate 531 and the driving member 537.

The support ring 533 may surround the circumference of the transfer plate 531. The support ring 533 may support an edge of the transfer plate 531. The support ring 533 may support the substrate W in such a way that the substrate W is located at a regular position after the substrate W is put on the transfer plate 531.

The driving member 537 may drive the transfer plate 531. The driving member 537 may horizontally and vertically move the transfer plate 531. The driving member 537 may move the transfer plate 531 to a first position 501 and a second position 502. The transfer plate 531 disposed at the first position 501 may be adjacent to the first sidewall 511. The second position 502 may be near to the second sidewall 513 and may correspond to a position over a heating plate 551.

The heating unit 550 may heat the substrate W to a setting temperature. The heating unit 550 may include the heating plate 551, a lift pin 553, a cover 555, and an actuator 557.

A heating member heating the substrate W may be provided within the heating plate 551. For example, the heating member may be a heating coil. Alternatively, heat-generating patterns may be provided in the heating plate 551. The heating plate 551 may have a cylindrical shape. A pin hole 554 receiving the lift pin 553 may be formed in the heating plate 551.

The pin hole 554 may correspond to a movement path of the lift pin 553 when the lift pin 553 vertically moves the substrate W. The pin hole 554 may vertically penetrate the heating plate 551 and may be provided in plurality.

The lift pin 553 may be vertically moved by an elevating tool (not shown). The lift pin 553 may safely load the substrate W onto the heating plate 551. The lift pin 553 may elevate the substrate W to a position spaced apart from the heating plate 551 by a certain distance.

The cover 555 may be located over the heating plate 551. The cover 555 may have a cylindrical shape. The cover 555 may have a heating space therein. The cover 555 may be moved upward from the heating plate 551 by the actuator 557 so as to be located over the heating plate 551 when the substrate W moves onto the heating plate 551. When the substrate W is heated by the heating plate 551, the cover 555 may be moved downward by the actuator 557 to form the heating space in which the substrate W is heated.

The actuator 557 may be fixedly combined with the cover 555 by a supporting part 558. The actuator 557 may move the cover 555 in up and down directions when the substrate W is loaded on or unloaded from the heating plate 551. For example, the actuator 557 may include a cylinder.

The cooling unit 570 may cool the heating plate 551 or a treated substrate W. The cooling unit 570 may be provided within the transfer plate 531. For example, the cooling unit 570 may include a cooling fluid path. Cooling water may be supplied into the cooling fluid path to cool the substrate W or the heating plate 551.

The controller 590 may control the transfer unit 530 and the cooling unit 570.

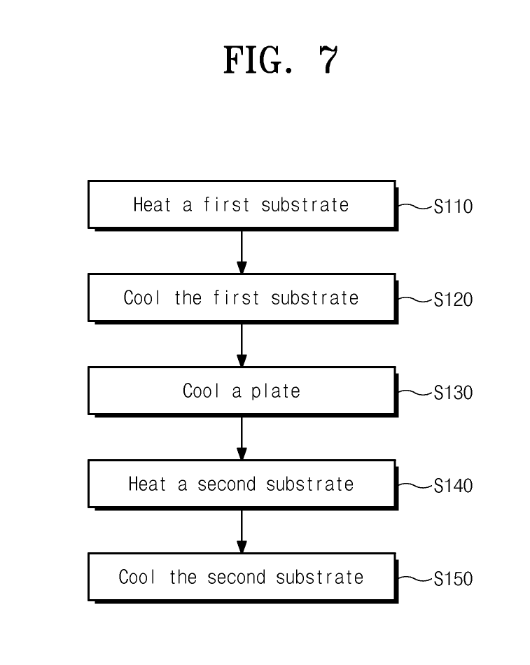

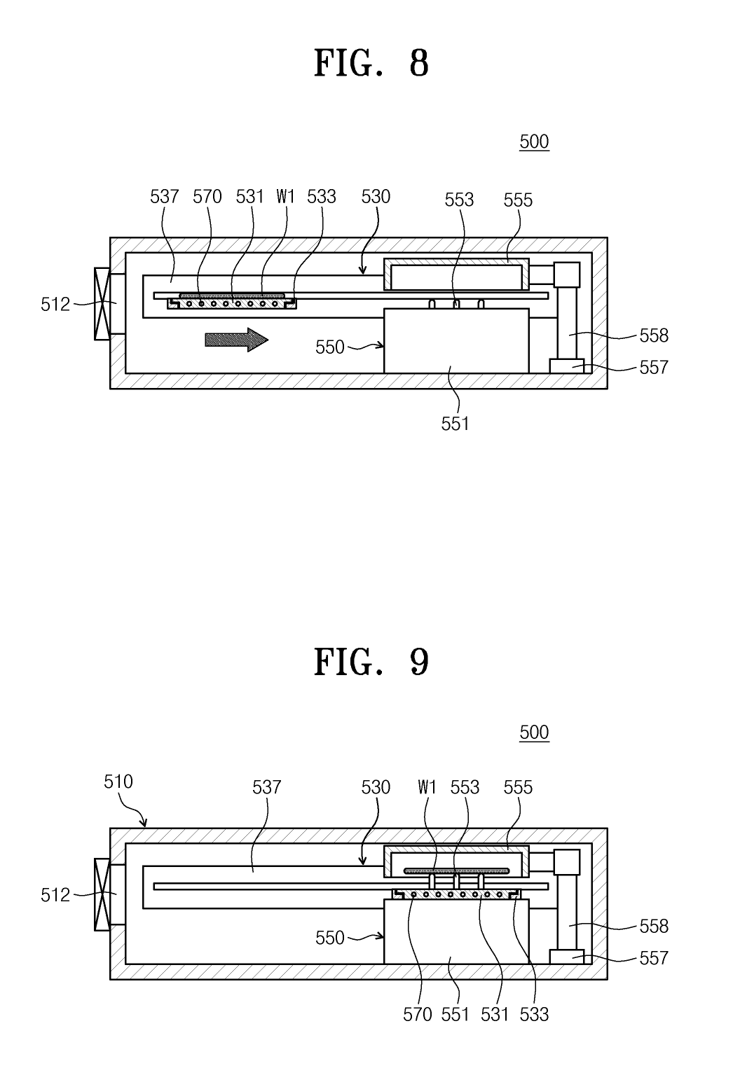

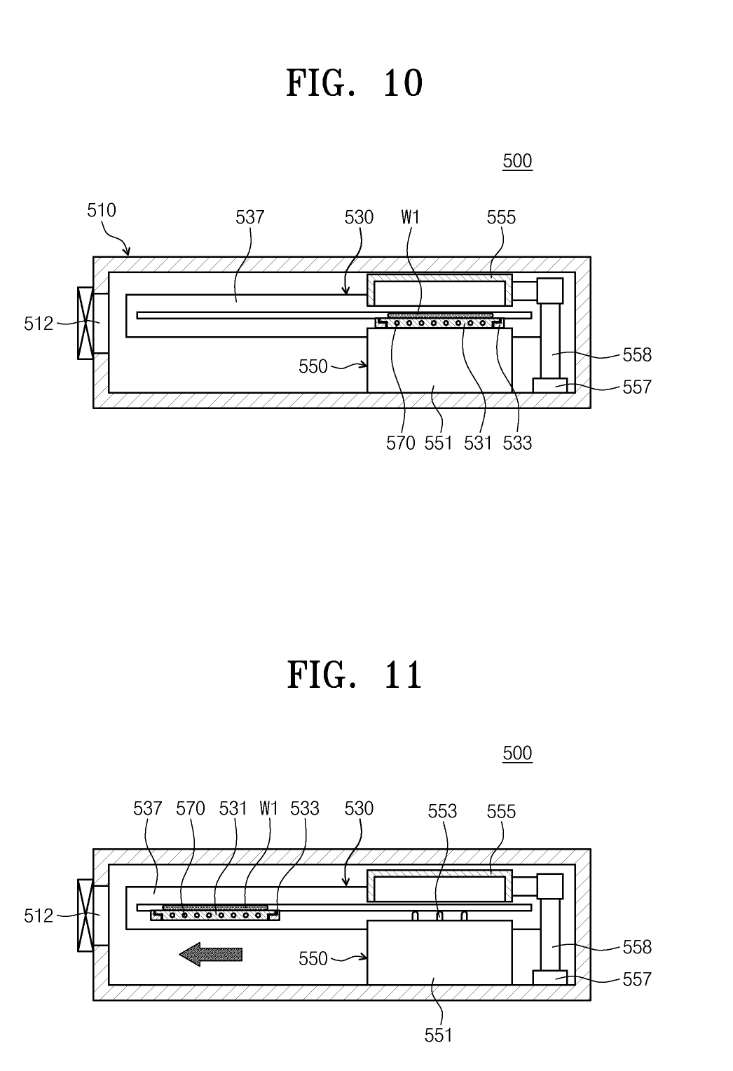

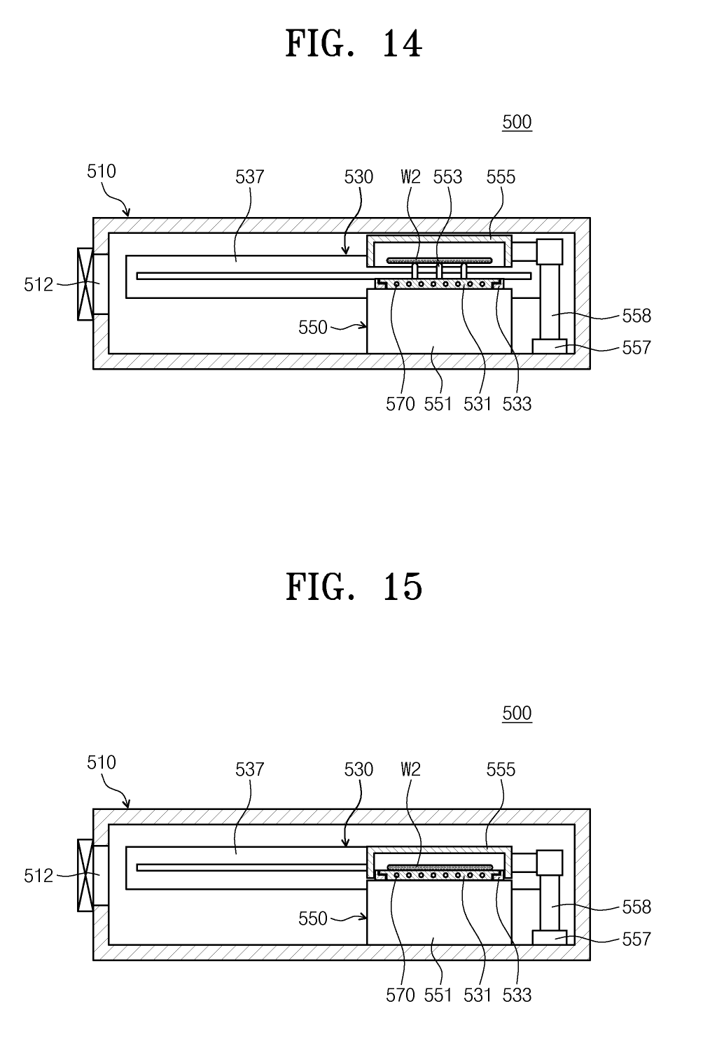

FIG. 7 is a flow chart illustrating a method for treating a substrate in a bake unit according to example embodiments of the inventive concepts. FIGS. 8 to 16 are cross-sectional views illustrating a method for treating a substrate according to example embodiments of the inventive concepts. Referring to FIGS. 7 to 16, the bake process may heat a first substrate W1 included in a first group to a first temperature (T1) and then may heat a second substrate W2 included in a second group to a second temperature (T2). Each of the first and second groups may include one substrate or a plurality of substrates. The substrates included in each of the first and second groups may correspond to substrates provided in one cassette.

A method for treating a substrate may include heating a first substrate (S110), cooling the first substrate (S120), cooling a plate (S130), heating a second substrate (S140), and cooling the second substrate (S150).

Heating the first substrate (S110) may include heating the first substrate W1 included in the first group to the first temperature (T1). FIGS. 8 to 10 sequentially show heating the first substrate (S110). The first substrate W1 may be transferred to the transfer plate 531 in the housing 510. The first substrate W1 transferred to the transfer plate 531 may be moved from the first position 501 to the second position 502 by the driving member 537 in a state that the cover 555 is moved upward to be vertically spaced apart from the heating plate 551. The transfer plate 531 may put down the first substrate W1 on the heating plate 551. The actuator 557 may move the cover 555 in the down direction to provide the heating space. The heating plate 551 may heat the first substrate W1 to the first temperature (T1).

Cooling the first substrate (S120) may be performed after heating the first substrate (S110). FIG. 11 shows cooling the first substrate (S120). The first substrate W1 may be transferred from the heating plate 551 to the transfer plate 531. The first substrate W1 laid on the transfer plate 531 may be moved from the second position 502 to the first position 501. The first substrate W1 may be cooled by the cooling unit 570 while or after the first substrate W1 is moved to the first position 501.

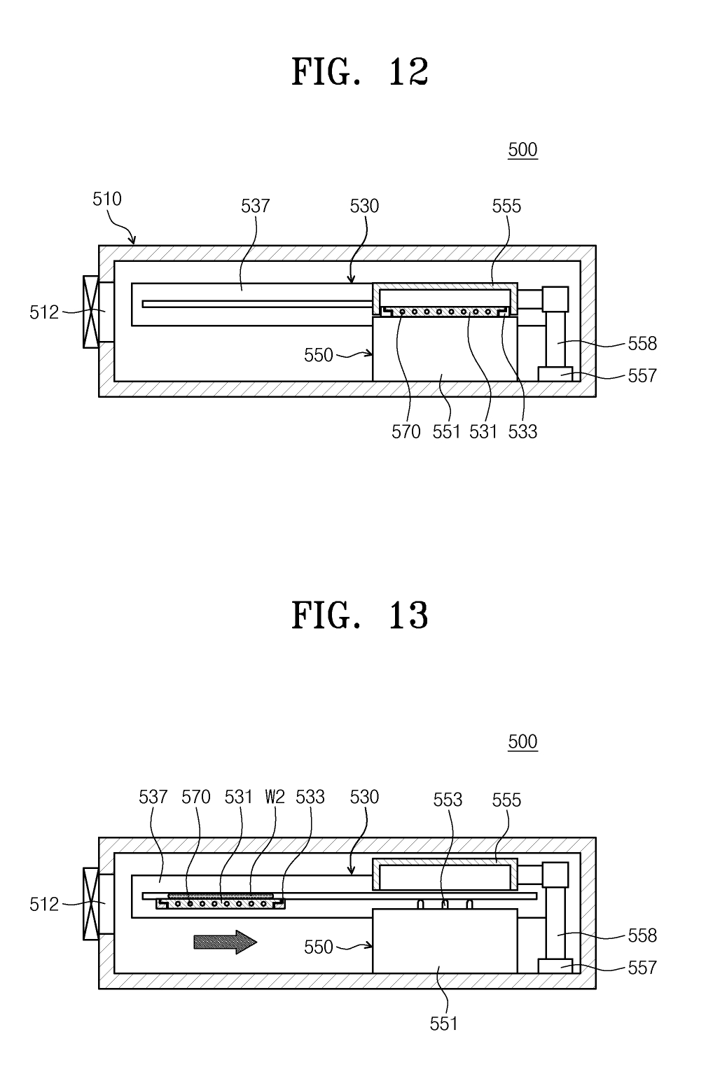

Cooling the plate (S130) may be performed after cooling the first substrate (S120). FIG. 12 shows cooling the plate (S130). The transfer plate 531 on which a substrate is not laid may be moved from the first position 501 to the second position 502 by the driving member 537. The transfer plate 531 may be in contact with the heating plate 551 or may be disposed at a position adjacent to the heating plate 551. The cooling unit 570 may reduce a temperature of the heating plate 551 from the first temperature (T1) to the second temperature (T2) lower than the first temperature (T1). After the heating plate 551 is cooled, the transfer plate 531 may be moved from the second position 502 to the first position 501.

Heating the second substrate (S140) may be performed after cooling the plate (S130). In heating the second substrate (S140), the second substrate W2 included in the second group may be heated to the second temperature (T2). FIGS. 13 to 15 sequentially show heating the second substrate (S140). The second substrate W2 may be transferred to the transfer plate 531 in the housing 510. The second substrate W2 transferred to the transfer plate 531 may be moved from the first position 501 to the second position 502 by the driving member 537 in a state that the cover 555 is moved upward to be vertically spaced apart from the heating plate 551. The transfer plate 531 may put down the second substrate W2 on the heating plate 551. The actuator 557 may move the cover 555 in the down direction to provide the heating space. The heating plate 551 may heat the second substrate W2 to the second temperature (T2).

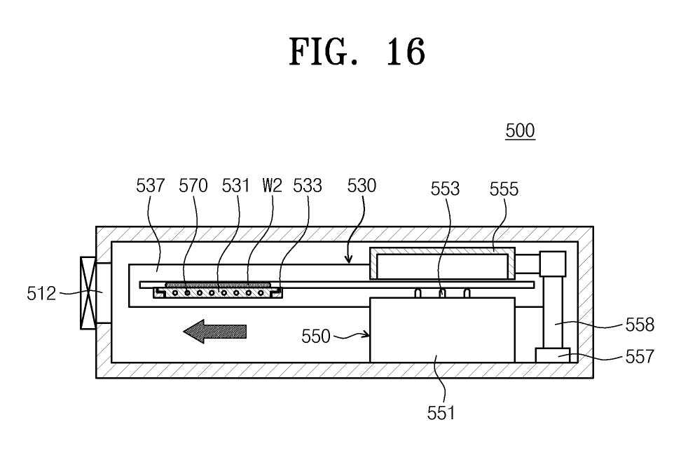

Cooling the second substrate (S150) may be performed after heating the second substrate (S140). FIG. 16 shows cooling the second substrate (S150). The second substrate W2 may be transferred from the heating plate 551 to the transfer plate 531. The second substrate W2 laid on the transfer plate 531 may be moved from the second position 502 to the first position 501. The second substrate W2 may be cooled by the cooling unit 570 while or after the second substrate W2 is moved to the first position 501.

Referring again to FIGS. 1 to 3, the development module 402 may perform a development process and a thermal treatment process (e.g., a heating process and a cooling process). In the development process, a development solution may be supplied to remove a portion of the photoresist for obtaining a pattern on the substrate W. The thermal treatment process may be performed before and after the development process. The development module 402 may include a solution-treatment chamber 460, a bake unit 500, and a transfer chamber 480. The solution-treatment chamber 460, the transfer chamber 480, and the bake unit 500 may be sequentially arranged along the second direction 14. The solution-treatment chamber may be provided as a development chamber. The development chamber 460 and the bake unit 500 may be spaced apart from each other in the second direction 14 with the transfer chamber 480 interposed therebetween. The development chamber 460 may be provided in plurality. In more detail, the development chamber 460 may be provided in plurality along each of the first and third directions 12 and 16.

The transfer chamber 480 and the second buffer 330 of the buffer module 300 may be arranged along the first direction 12. The development part robot 482 and a guide rail 483 may be disposed in the transfer chamber 480. The transfer chamber 480 may have a substantially rectangular shape when viewed from a plan view. The development part robot 482 may transfer a substrate W among the bake units 500, the development chambers 460, and the second buffer 330 and the cooling chamber 350 of the buffer module 300. The guide rail 483 may be disposed in such a way that its longitudinal direction is parallel to the first direction 12. The guide rail 483 may guide the development part robot 482 such that the development part robot 482 is linearly movable in the first direction 12. The development part robot 482 may include a hand 484, an arm 485, a supporter 486, and a pedestal 487. The hand 484 may be fixedly installed on the arm 485. The arm 485 may have a retractile and protrusile structure, and thus, the hand 484 may be movable in a horizontal direction. The supporter 486 may be disposed such that its longitudinal direction is parallel to the third direction 16. The arm 485 may be coupled to the supporter 486 so as to be linearly movable along the supporter 486 in the third direction 16. The supporter 486 may be fixedly combined with the pedestal 487, and the pedestal 487 may be coupled to the guide rail 483 so as to be movable along the guide rail 483.

The development chambers 460 may have the same structure. However, kinds of development solutions respectively used in the development chambers 460 may be different from each other or may be the same as each other. The development chamber 460 may remove a region, to which light is irradiated, of the photoresist formed on the substrate W. At this time, a region, to which the light is irradiated, of a protection layer may also be removed. In other embodiments, regions, to which light is not irradiated, of the photoresist and the protection layer may be removed according to a kind of the used photoresist.

The development chamber 460 may include a housing 461, a support plate 462, and a nozzle 463. The housing 461 may have a cup shape of which a top end is opened. The support plate 462 may be located in the housing 461 and may support a substrate W. The support plate 462 may be provided to be rotatable. The nozzle 463 may supply the development solution onto the substrate W disposed on the support plate 462. The nozzle 463 may have a circular pipe shape and may supply the development solution to a center of the substrate W. In other embodiments, the nozzle 463 may have a length corresponding to a diameter of the substrate W, and a discharge opening of the nozzle 463 may have a slit shape. In addition, the development chamber 460 may further include a nozzle 464 that supplies a cleaning solution (e.g., deionized water) to clean a surface of the substrate W supplied with the development solution.

The bake unit 500 provided to the development module 402 may be the substantially same as the bake unit 500 of the coating module 401 described above.

As described above, the coating module 401 and the development module 402 may be provided to be separated from each other in the coating and development module 400. In addition, the coating module 401 and the development module 402 may have the same chamber arrangement when viewed from a plan view.

The interface module 700 may transfer a substrate W. The interface module 700 may include a frame 710, a first buffer 720, a second buffer 730, and an interface robot 740. The first buffer 720, the second buffer 730, and the interface robot 740 may be located in the frame 710. The second buffer 730 and the first buffer 720 may be spaced apart from each other by a predetermined distance and may be stacked. The first buffer 720 may be higher than the second buffer 730.

The interface robot 740 may be spaced apart from the first and second buffers 720 and 730 in the second direction 14. The interface robot 740 may transfer a substrate W among the first buffer 720, the second buffer 730, and an exposure apparatus 900.

The first buffer 720 may temporarily keep the substrates W coated by the coating process before the substrates W are transferred to the exposure apparatus 900. The second buffer 730 may temporarily keep the substrates W exposed by the exposure process before the substrates W are transferred to the development module 402. The first buffer 720 may include a housing 721 and a plurality of supporters 722. The supporters 722 may be disposed in the housing 721 and may be spaced apart from each other along the third direction 16. One substrate W may be laid on each of the supporters 722. The housing 721 may have openings that can face the interface robot 740 and a pre-treatment robot, respectively, and thus, the interface robot 740 and the pre-treatment robot may carry a substrate W onto the supporter 722 or may take a substrate W out of the supporter 722. The second buffer 730 may have a similar structure to the first buffer 720. The interface module 700 may be provided with only the buffers 720 and 730 and the robot 720 without a chamber performing a predetermined process on a wafer.

According to an embodiment of the inventive concepts, the cooling unit may be provided to the transfer plate, so efficiency of the bake process may be improved.

According to an embodiment of the inventive concepts, the cooling unit may be provided to the transfer plate, so the heating unit heating a substrate may be cooled in a short time.

According to an embodiment of the inventive concepts, the cooling unit may be provided to the transfer plate, so the heating plate or the substrate may be cooled by both the method using the cooling unit and a natural cooling method. As a result, the cooling time may be minimized.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A bake unit comprising:
a housing;
a heating unit located in the housing, the heating unit comprising a heating plate heating a substrate;
a transfer unit located in the housing, the transfer unit transferring a substrate; and
a cooling unit cooling the heating plate or a heated substrate,
wherein the transfer unit comprises: a transfer plate on which a substrate is laid, and
wherein the cooling unit is provided to the transfer plate.

2. The bake unit of claim 1, wherein the cooling unit includes a cooling fluid path provided within the transfer plate.

3. The bake unit of claim 2, wherein the housing comprises:
a first sidewall through which an entrance is formed, a substrate transferred through the entrance; and
a second sidewall opposite to the first sidewall,
wherein the heating unit is located to be more adjacent to the second sidewall than to the first sidewall.

4. The bake unit of claim 3, wherein the heating unit further comprises:
a cover disposed on the heating plate, the cover providing a heating space including the heating plate; and
an actuator moving the cover in up and down directions.

5. The bake unit of claim 4, wherein the heating unit further comprises:
a lift pin movable through a pin hole, formed in the heating plate, along up and down directions, the lift pin transferring a substrate to the transfer unit.

6. The bake unit of claim 5, wherein the transfer unit further comprises: a driving member transferring the transfer plate to a first position and a second position,
wherein the first position is adjacent to the first sidewall, and
wherein the second position is near to the second sidewall and is over the heating plate.

7. The bake unit of claim 6, wherein a guide hole into which the lift pin is inserted is formed in the transfer plate to prevent the transfer plate from interfering or colliding with the lift pin when the transfer plate is moved from the first position to the second position, and
wherein the guide hole extends from an outer side surface of the transfer plate to the inside of the transfer plate.

8. The bake unit of claim 1, further comprising:
a controller controlling the transfer unit and the cooling unit,
wherein, when a temperature of the heating plate is reduced, the controller controls the transfer unit and the cooling unit in such a way that the transfer plate comes in contact with or is located to be adjacent to the heating plate and then the heating plate is cooled by the cooling unit.

9. The bake unit of claim 1, further comprising:
a controller controlling the transfer unit and the cooling unit,
wherein, when a substrate heated on the heating plate is cooled, the controller controls the transfer unit and the cooling unit in such a way that a substrate completely treated on the heating plate is located on the transfer plate and then the substrate is cooled using the cooling unit.

10. A substrate treating apparatus comprising:
a bake unit performing a bake process on a substrate;
a solution-treatment chamber supplying a solution onto a substrate to perform a process; and
a transfer chamber transferring a substrate between the bake unit and the solution-treatment chamber,
wherein the bake unit comprises:
a housing;
a heating unit located in the housing, the heating unit comprising a heating plate heating a substrate;
a transfer unit located in the housing, the transfer unit transferring a substrate; and
a cooling unit cooling the heating plate or a heated substrate,
wherein the transfer unit comprises: a transfer plate on which a substrate is laid, and
wherein the cooling unit is provided to the transfer plate.

11. The substrate treating apparatus of claim 10, wherein the cooling unit comprises: a cooling fluid path provided within the transfer plate.

12. The substrate treating apparatus of claim 11, wherein the housing comprises:
a first sidewall through which an entrance is formed, a substrate transferred through the entrance; and
a second sidewall opposite to the first sidewall,
wherein the heating unit is disposed to be more adjacent to the second sidewall than to the first sidewall.

13. The substrate treating apparatus of claim 12, wherein the heating unit further comprises:
a cover disposed on the heating plate, the cover providing a heating space including the heating plate; and
an actuator moving the cover in up and down directions.

14. The substrate treating apparatus of claim 13, wherein the heating unit further comprises:
a lift pin movable through a pin hole, formed in the heating plate, along up and down directions, the lift pin transferring a substrate to the transfer unit.

15. The substrate treating apparatus of claim 14, wherein the transfer unit further comprises: a driving member transferring the transfer plate to a first position and a second position,
wherein the first position is adjacent to the first sidewall, and
wherein the second position is near to the second sidewall and is over the heating plate.

16. The substrate treating apparatus of claim 15, wherein a guide hole into which the lift pin is inserted is formed in the transfer plate to prevent the transfer plate from interfering or colliding with the lift pin when the transfer plate is moved from the first position to the second position, and
wherein the guide hole extends from an outer side surface of the transfer plate to the inside of the transfer plate.

17. The substrate treating apparatus of claim 10, further comprising:
a controller controlling the transfer unit and the cooling unit,
wherein, when a temperature of the heating plate is reduced, the controller controls the transfer unit and the cooling unit in such a way that the transfer plate comes in contact with or is located to be adjacent to the heating plate and then the heating plate is cooled by the cooling unit.

18. The substrate treating apparatus of claim 10, further comprising:
a controller controlling the transfer unit and the cooling unit,
wherein, when a substrate heated on the heating plate is cooled, the controller controls the transfer unit and the cooling unit in such a way that a substrate completely treated on the heating plate is located on the transfer plate and then the substrate is cooled using the cooling unit.

19. A method for treating a substrate, the method comprising:
heating a first substrate included in a first group to a first temperature by a heating plate;
cooling the heating plate using a cooling unit provided to a transfer plate transferring a substrate to the heating plate; and
heating a second substrate included in a second group to a second temperature lower than the first temperature by the heating plate.

20. The method of claim 19, wherein cooling the heating plate comprises:
cooling the heating plate using the cooling unit after the transfer plate comes in contact with or is located to be adjacent to the heating plate when a temperature of the heating plate is reduced to the second temperature.

21. The method of claim 19, wherein cooling the heating plate comprises:
cooling the heating plate using the cooling unit after the transfer plate comes in contact with or is located to be adjacent to the heating plate in a state that a substrate is removed from the transfer plate.

22. The method of claim 20, wherein cooling the heating plate comprises:
cooling the heating plate using a cooling gas supplied to a bottom surface of the heating plate while cooling the heating plate by the cooling unit.

23. The method of claim 20, further comprising:
cooling the first substrate using the cooling unit after locating the first substrate, completely treated after heating the first substrate to the first temperature on the heating plate, on the transfer plate,
wherein cooling the first substrate is performed before cooling the heating plate.

24. The method of claim 19, further comprising:
cooling the second substrate using the cooling unit after locating the second substrate, completely treated after heating the second substrate to the second temperature on the heating plate, on the transfer plate.

25. The method of claim 19, wherein the cooling unit comprises: a cooling fluid path provided within the transfer plate.
